(19) United States
(12) Patent Application Publication
(10) Pub. No.: US 2026/0167013 A1
(43) Pub. Date: Jun. 18, 2026

(54) POWER MODULE FOR VEHICLE INCLUDING EMBEDDED CAPACITOR AND MOTOR DRIVING APPARATUS INCLUDING THE SAME

(71) Applicants: HYUNDAI MOTOR COMPANY, Seoul (KR); KIA CORPORATION, Seoul (KR)

(72) Inventors: Dong Hwan Lee, Hwaseong-si (KR); Han Jin Do, Hwaseong-si (KR); Jin Myeong Yang, Hwaseong-si (KR); Sung Won Park, Hwaseong-si (KR)

(73) Assignees: HYUNDAI MOTOR COMPANY, Seoul (KR); KIA CORPORATION, Seoul (KR)

(21) Appl. No.: 19/201,868

(22) Filed: May 7, 2025

(30) Foreign Application Priority Data
Dec. 13, 2024 (KR) 10-2024-0185635

(51) Int. Cl. B60L 15/00; H01L 23/00; H01L 23/31; H01L 23/373; H01L 25/07; H02P 27/06; H10D 80/20

(52) U.S. Cl. CPC B60L 15/007; H10D 80/20; H10W 40/255; H10W 74/114; H10W 90/00; B60L 2210/44; H02P 27/06; H10W 72/884; H10W 90/734; H10W 90/755

(57) ABSTRACT

A power module for a vehicle is provided. The power module includes a first circuit board including a first insulating layer and a first metal layer disposed on the first insulating layer, a lead frame including a plurality of direct current (DC) electrodes arranged on one side of the first circuit board, a first switching unit electrically connected to the plurality of DC electrodes and disposed on the first circuit board, and an embedded capacitor electrically connected between the plurality of DC electrodes. The embedded capacitor is disposed to overlap at least one of the first insulating layer and the first metal layer in a direction in which the first insulating layer and the first metal layer face each other.

### CROSS-REFERENCE TO RELATED APPLICATION(S)

This application claims benefit of priority to Korean Patent Application No. 10-2024-0185635 filed on Dec. 13, 2024 in the Korean Intellectual Property Office, the disclosure of which is incorporated herein by reference in its entirety.

### TECHNICAL FIELD

The present disclosure relates to a power module for a vehicle including an embedded capacitor and a motor driving apparatus including the same.

### BACKGROUND

Eco-friendly vehicles may include hybrid vehicles (HEVs), plug-in hybrid vehicles (PHEVs), electric vehicles (EVs), fuel cell electric vehicles (FCEVs), etc. A power module of eco-friendly vehicles receives DC current from a high-voltage battery, converts the DC current into AC current, supplies the same to a motor, and the torque and rotational speed of the motor are controlled by adjusting the magnitude and phase of the AC current.

### SUMMARY

An electrical path of a power module for a vehicle may act as parasitic inductance, and the parasitic inductance may cause instability (e.g., fluctuations, surges, or ringing) of current and/or voltage.

An aspect of the present disclosure is to provide a power module for a vehicle including an embedded capacitor, and a motor driving apparatus including the same, capable of (e.g., efficiently) reducing the influence of parasitic inductance of the power module for a vehicle (e.g., fluctuations, surges, or ringing of voltage/current due to switching for power conversion) and increasing the power conversion (e.g., efficiency) of the power module (e.g., switching unit) for a vehicle or reducing the (e.g., required) specifications (e.g., withstand voltage characteristics).

According to an aspect of the present disclosure, a power module for a vehicle includes a first circuit board including a first insulating layer and a first metal layer disposed on the first insulating layer. The power module also includes a lead frame including a plurality of direct current (DC) electrodes arranged on one side of the first circuit board, a first switching unit electrically connected to the plurality of DC electrodes and disposed on the first circuit board, and an embedded capacitor electrically connected between the plurality of DC electrodes. The embedded capacitor is disposed to overlap at least one of the first insulating layer and the first metal layer in a direction in which the first insulating layer and the first metal layer face each other.

The power module may further include a fused portion connected between the embedded capacitor and the first metal layer. The fused portion may include a conductive material having a lower melting point than that of the first metal layer.

The embedded capacitor may include a capacitor body, a plurality of capacitor electrodes arranged in the capacitor body, and a capacitor bonding wire connected to one of the plurality of capacitor electrodes. The other of the plurality of capacitor electrodes may be electrically connected to the first metal layer, and the capacitor bonding wire may connect one of the plurality of capacitor electrodes to the first metal layer.

The power module may further include an encapsulant disposed on the first circuit board and encapsulating the first switching unit and the embedded capacitor.

The power module may further include a second circuit board including a second insulating layer and a second metal layer disposed on the second insulating layer. The embedded capacitor may be disposed between the first circuit board and the second circuit board.

The embedded capacitor may include a capacitor body and a plurality of capacitor electrodes arranged in the capacitor body, and one of the plurality of capacitor electrodes may be electrically connected to the first metal layer and the other of the plurality of capacitor electrodes is electrically connected to the second metal layer.

The power module may further include a via spacer disposed between the first circuit board and the second circuit board to electrically connect the first metal layer to the second metal layer.

The power module may further include a switching unit spacer disposed between the first switching unit and the second circuit board to electrically connect the first switching unit to the second metal layer.

The power module may further include a capacitor spacer disposed between the first and second circuit boards to overlap the embedded capacitor in a direction in which the first and second circuit boards face each other. The other of the plurality of capacitor electrodes are electrically connected to the second metal layer through the capacitor spacer.

The embedded capacitor may include a capacitor body and a plurality of capacitor electrodes arranged in the capacitor body. The plurality of capacitor electrodes may be electrically connected to a plurality of separated patterns of the first metal layer, and the embedded capacitor may be disposed in a bridge structure crossing between the plurality of patterns.

A portion of the lead frame may be disposed to overlap at least one of the first insulating layer and the first metal layer in a direction in which the first insulating layer and the first metal layer face each other, and the embedded capacitor may be disposed to not overlap the lead frame in the direction in which the first insulating layer and the first metal layer face each other.

The lead frame may further include a plurality of alternating current (AC) electrodes electrically connected to the first switching unit, and the plurality of DC electrodes may be arranged adjacently so as not to have the plurality of AC electrodes therebetween.

The power module may further include a signal lead electrically connected to the first switching unit and disposed on the other side of the first circuit board.

The plurality of DC electrodes may be electrically connected to a DC link capacitor and a battery outside the power module for a vehicle, and the plurality of AC electrodes may be electrically connected to a motor outside the power module for a vehicle.

The power module may further include a second switching unit disposed on the first circuit board, and a third switching unit arranged on the first circuit board. The first switching unit includes a plurality of first semiconductor chips, the second switching unit includes a plurality of second semiconductor chips, and the third switching unit includes a third semiconductor chip.

The first switching unit may be disposed in a central portion of the first circuit board, the second switching unit may be disposed on the outside of the first switching unit on the first circuit board, and the third switching unit may be disposed on the outside of the first switching unit on the first circuit board.

According to another aspect of the present disclosure, a motor driving apparatus includes the power module for a vehicle (e.g., as described above). The first switching unit includes a 1-1 switching element and a 1-2 switching element and corresponds to one leg of a first inverter, the second switching unit includes a 2-1 switching element and a 2-2 switching element and corresponds to one leg of a second inverter, and one end of the third switching unit is connected between a first node between the 1 -1 switching element and the 1-2 switching element and a second node between the 2-1 switching element and the 2-2 switching element and constitutes part of a changeover switch.

### BRIEF DESCRIPTION OF DRAWINGS

The above and other aspects and features of the present disclosure may be understood from the following detailed description, taken in conjunction with the accompanying drawings.

FIG. 1A is a circuit diagram illustrating that an embedded capacitor of a power module for a vehicle cancels out parasitic inductance according to an embodiment of the present disclosure.

FIG. 1B is a circuit diagram illustrating a power module for a vehicle and a motor driving apparatus including the same according to an embodiment of the present disclosure.

FIG. 2 is a plan view illustrating a power module for a vehicle according to an embodiment of the present disclosure.

FIGS. 3A, 3B, 3C, and 3D are side views illustrating a power module for a vehicle according to an embodiment of the present disclosure.

### DETAILED DESCRIPTION

While the present disclosure may be modified in various manners and may take on various alternative forms, specific embodiments thereof are shown in the drawings and described in detail below. However, the present disclosure is not limited to the particular forms disclosed, but on the contrary, the present disclosure covers modifications, equivalents, and alternatives falling within the spirit and scope of the present disclosure.

It may be understood that, although the terms “first,” “second,” and the like may be used herein to describe various elements, these elements are not limited by these terms. These terms are used to distinguish one element from another. For example, a first element may be termed a second element, and a second element may similarly be termed a first element without departing from the scope of the present disclosure. As used herein, the term “and/or” includes combinations of one or more of the associated listed items.

The terms used herein to describe embodiments of the present disclosure are not intended to limit the scope of the present disclosure. The articles “a,” and “an” are singular in that they have a single referent, however the use of the singular form in the present document should not preclude the presence of more than one referent. In other words, elements of the present disclosure referred to in the singular may number one or more, unless the context indicates otherwise. It may be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless provided in a different manner, the terms used herein including technical and scientific terms have the same meanings as understood by those skilled in the art to which the present disclosure pertains. Such terms as provided in generally used dictionaries should be construed as having the same meanings as those of the contexts of the related art, and unless provided in the application, the terms should not be construed to have (e.g., ideally or excessively) formal meanings.

In this specification, vehicles refer to a variety of vehicles that move transported objects, such as people, animals, or goods, from a starting point to a destination. These vehicles are not limited to vehicles that run on roads or tracks.

Hereinafter, embodiments of the present disclosure are described with reference to the accompanying drawings.

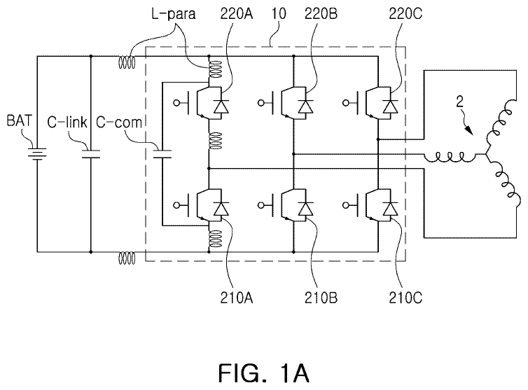

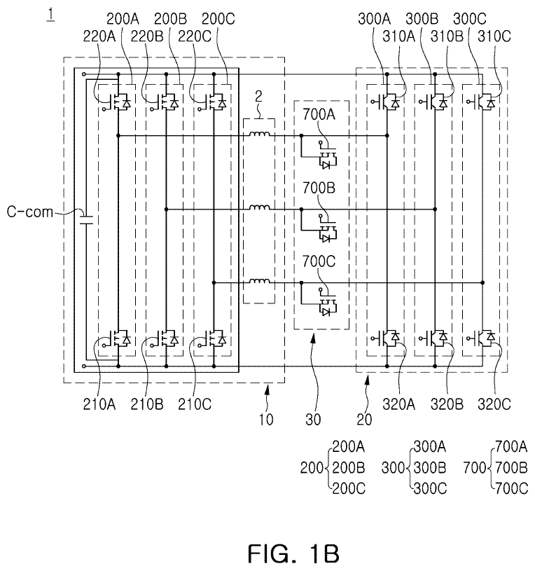

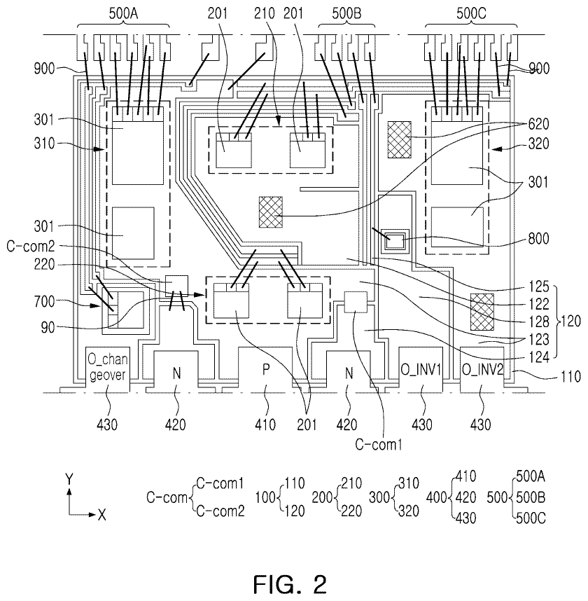

Referring to FIG. 1A, a power module for a vehicle according to an embodiment of the present disclosure may include a first inverter 10, may be electrically connected to a DC link capacitor C-link and a battery BAT outside the power module for a vehicle through a plurality of DC electrodes (e.g., 410 and 420 of FIG. 2), and may be electrically connected to a motor 2 outside the power module for a vehicle through an AC electrode (e.g., 430 of FIG. 2). Referring to FIG. 1B, depending on the embodiment (e.g., design), the power module for a vehicle may further include a second inverter 20 and a changeover switch 30.

Referring to FIGS. 1A and 1B, the first inverter 10 may include a first switching unit 200, and the first switching unit 200 may include three first switching units 200A, 200B, and 200C corresponding to three phases, respectively. The three first switching units 200A, 200B, and 200C may include three 1-1 switching elements 210A, 210B, and 210C and three 1-2 switching elements 220A, 220B, and 220C, respectively, and may correspond to one leg of the first inverter 10.

The second inverter 20 may include a second switching unit 300, and the second switching unit 300 may include three second switching units 300A, 300B, and 300C corresponding to three phases, respectively. The three second switching units 300A, 300B, and 300C may include three 2-1 switching elements 310A, 310B, and 310C and three 2-2 switching elements 320A, 320B, and 320C, respectively, and may correspond to one leg of the second inverter 20.

The changeover switch 30 may include a third switching unit 700, and the third switching unit 700 may include three third switching units 700A, 700B, and 700C corresponding to three phases, respectively. One end of each of the third switching unit 700A, 700B, and 700C is connected between a first node between the 1-1 switching elements 210A, 210B, and 210C and the 1-2 switching elements 220A, 220B, and 220C and a second node between the 2-1 switching elements 310A, 310B, and 310C and the 2-2 switching elements 320A, 320B, and 320C and may constitute part of the changeover switch 30.

When a direct current (DC) of the battery BAT provided in an electric vehicle is input to a motor driving apparatus 1 for a vehicle, the motor driving apparatus 1 for a vehicle may convert the input DC current into alternating current (AC) and output the same to the motor 2 to operate the motor 2. The first and second inverters 10 and 20 may convert the DC current into AC current.

The first inverter 10 may be operated at (e.g., all) times, and the second inverter 20 may be operated together with the first inverter 10 when the motor 2 requires high output. Accordingly, the motor driving apparatus 1 for a vehicle may increase the overall efficiency in a wide output range of the motor 2. The changeover switch 30 may connect the first inverter 10 to the second inverter 20, and may be turned ON to provide a Y connection between each phase winding of the motor 2 when (e.g., only) the first inverter 10 is operated, and may be turned OFF when the second inverter 20 is also operated.

Referring to FIG. 2, the first switching unit 200 may include at least one of a plurality of first semiconductor chips 201, the second switching unit 300 may include at least one of a plurality of second semiconductor chips 301, and the third switching unit 700 may include a third semiconductor chip.

For example, the first switching unit 200 and the third switching unit 700 may be implemented as silicon carbide (SiC) chips, and the second switching unit 300 may be implemented as a Si chip. The second switching unit 300 may be selectively turned off, and thus, the second switching unit 300 may be implemented as a (e.g., relatively) low-performance Si chip. The frequency of use of the first switching unit 200 and the third switching unit 700 may be (e.g., relatively) high compared to the second switching unit 300, and thus, the first switching unit 200 and the third switching unit 700 may be implemented as (e.g., relatively) high-performance SiC chips. The semiconductor type of each switching element described above are examples according to the present disclosure and may not necessarily be limited thereto, and various types of semiconductors may be applied.

The frequency of use of the first switching unit 200 may be higher than that of the second switching unit 300, and the number of switching elements of the first switching unit 200 may be greater than that of the third switching unit 700. Therefore, compared to the second switching unit 300 and the third switching unit 700, the first switching unit 200 may have a greater influence on the overall energy efficiency of the power module for a vehicle.

For example, the first switching unit 200 may be arranged in a central portion of a first circuit board 100, the second switching unit 300 may be disposed on the outside of the first switching unit 200 in the first circuit board 100, and the third switching unit 700 may be disposed on the outside of the first switching unit 200 in the first circuit board 100. Accordingly, an electrical distance between a lead frame 400 and the first switching unit 200 may be shortened, and parasitic impedance may also be reduced due to the simplification of the electrical path between the lead frame 400 and the first switching unit 200. The shortening of the electrical distance may refer to an increase in energy efficiency, and the increase in the energy efficiency of the first switching unit 200 may refer to an improvement in the overall energy efficiency of the power module for a vehicle. In addition, this structure may be a structure for minimizing an insulation distance of a signal lead 500 and may also reduce the overall size of the power module for a vehicle.

For example, the 1-2 switching elements 220A, 220B, and 220C of the first switching unit 200 and the 2-2 switching elements 320A, 320B, and 320C of the second switching unit 300 may be formed with the same potential difference, and by arranging the 1-2 switching elements 220A, 220B, and 220C of the first switching unit 200 and the 2-2 switching elements 320A, 320B, and 320C of the second switching unit 300 adjacently, an insulation distance other than the (e.g., required) insulation distance of the signal lead 500 may be eliminated, thereby reducing the size of the first circuit board 100.

The third switching unit 700 may be disposed adjacent to the 2-1 switching elements 310A, 310B, and 310C of the second switching unit 300. The third switching unit 700 may be formed to have the same potential difference as the 2-1 switching elements 310A, 310B, and 310C of the second switching unit 300, and since the third switching unit 700 and the 2-1 switching elements 310A, 310B, and 310C are arranged adjacent to each other, an insulation distance other than the (e.g., required) insulation distance of the signal lead 500 may be eliminated, thereby reducing the size of the first circuit board 100.

By disposing the signal lead 500 in a position adjacent to the 1-2 switching elements 220A, 220B, and 220C of the first switching unit 200, the insulation distance other than the (e.g., required) insulation distance of the signal lead 500 may be eliminated, thereby reducing the size of the first circuit board 100.

One end of the third switching unit 700 may be connected between the motor 2 and the second switching unit 300, and the other end thereof may be connected to the lead frame 400 so that, when they are mutually connected to be turned on outside the power module for a vehicle, they may be able to provide a Y-connection for each winding of the motor 2.

Referring to FIGS. 1A, 1B, and 2, each of the three 1-1 switching elements 210A, 210B, and 210C, the three 1-2 switching elements 220A, 220B, and 220C, the three 2-1 switching elements 310A, 310B, and 310C, the three 2-2 switching elements 320A, 320B, and 320C, the three third switching units 700A, 700B, and 700C (e.g., total of 15) may include a structure in which a transistor and a diode are combined and may provide a switching operation between an ON state and an OFF state of the transistor according to a control signal input from an external source of the power module for a vehicle through a lead frame (e.g., 400 in FIG. 2). For example, the transistor may be implemented as an insulated gate bipolar transistor (IGBT) or a metal oxide semiconductor field effect transistor (MOSFET), but is not limited thereto.

The switching operation between the ON state and the OFF state of each switching element may cause a rapid change (e.g., recovery current of the switching element, and the like) in the current flowing between a drain terminal and a source terminal of the switching element. Capacitance of the DC link capacitor C-link may stabilize (e.g., balancing an instantaneous power difference between the battery and the first inverter) the instability (e.g., fluctuations, surges, or ringing) of the total DC current and total DC voltage of the first inverter 10 due to the rapid change in the current.

An electrical path between the switching element and the DC link capacitor C-link may act as a parasitic inductance L-para. In circuit theory, the product of the parasitic inductance L-para and a rate of rapid change in current due to the switching operation of the switching element may correspond to a voltage generated in the parasitic inductance L-para. Therefore, as the parasitic inductance L-para increases, the rapid change in current due to the switching operation of the switching element may increase the instability of the voltage (e.g., fluctuations, surges, or ringing). In this manner, the instability of the DC current and the instability of the DC voltage may be complementary to each other. Therefore, as the parasitic inductance L-para is lowered, the DC current and the DC voltage may be stabilized further overall.

The power module for a vehicle according to an embodiment of the present disclosure may include an embedded capacitor C-com. A current change occurring from the switching element may be affected by an output reactance of the switching element, and the output reactance may be reduced by an offset between a portion of the series parasitic inductance L-para (e.g., a portion corresponding between the embedded capacitor C-com and the DC link capacitor C-link) and a parallel capacitance of the embedded capacitor C-com. As the embedded capacitor C-com is connected closer to the 1-1 switching elements 210A, 210B, and 210C and the 1-2 switching elements 220A, 220B, and 220C, a portion of the series parasitic inductance L-para may occupy a larger proportion of the (e.g., entire) parasitic inductance L-para.

According to an embodiment of the present disclosure, the power module for a vehicle may include a structure in which the embedded capacitor C-com is embedded in the power module for a vehicle so that the embedded capacitor C-com is connected close to the 1-1 switching elements 210A, 210B, and 210C and the 1-2 switching elements 220A, 220B, and 220C, and thus, the parasitic inductance L-para may be (e.g., efficiently) offset. Accordingly, the influence of the parasitic inductance of the power module for a vehicle (e.g., fluctuation/surge/ringing of voltage/current due to switching for power conversion) may be (e.g., efficiently) reduced. In addition, by reducing the parasitic inductance L-para, the power module for a vehicle may further increase the power conversion efficiency (e.g., switching timing consistency between a plurality of switching elements) or reduce the (e.g., required) specifications of the power module for a vehicle (e.g., withstand voltage characteristics).

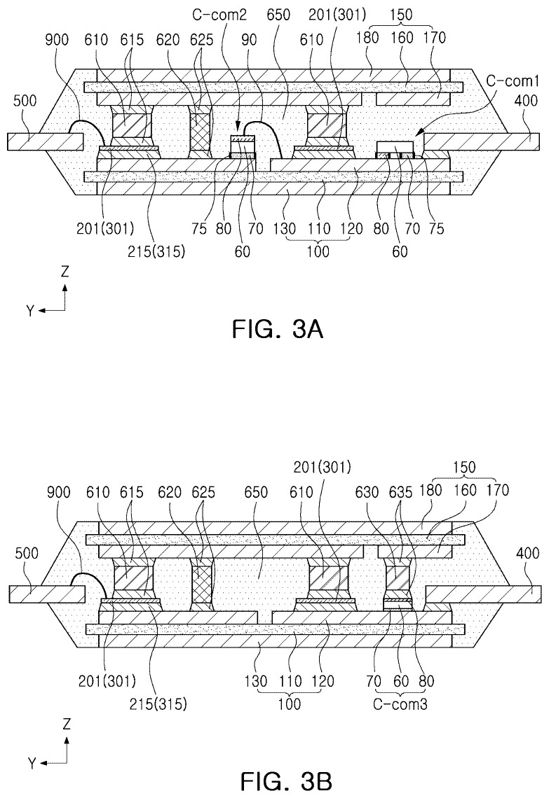

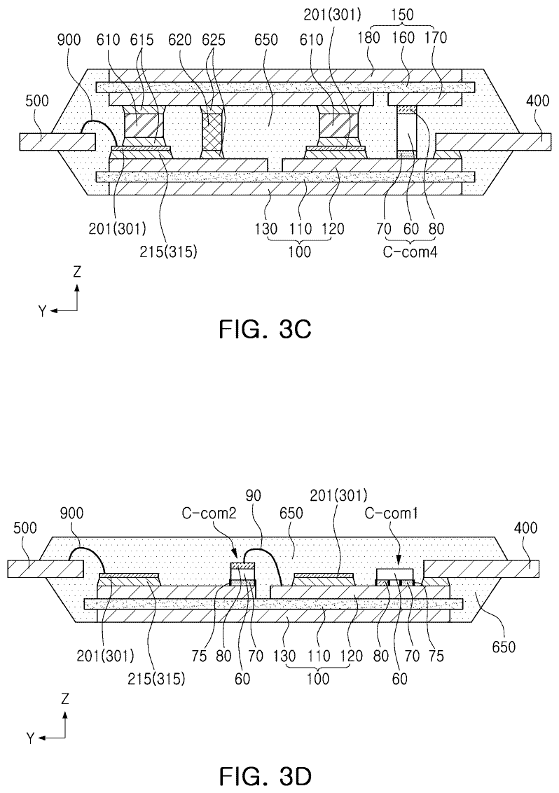

Referring to FIGS. 2 to 3D, the power module for a vehicle according to an embodiment of the present disclosure may include the first circuit board 100, the lead frame 400, the first switching unit 200, and embedded capacitors C-com, C-com1, C-com2, C-com3, and C-com4. Depending on the embodiment (e.g., design), the power module for a vehicle may further include at least one of a second circuit board 150 and the second switching unit 300. The first switching unit 200 may include at least one first semiconductor chip 201, and the second switching unit 300 may include at least one second semiconductor chip 301.

The first circuit board 100 may include a first insulating layer 110 and a first metal layer 120 disposed on the first insulating layer 110. The second circuit board 150 may include a second insulating layer 160 and a second metal layer 170 disposed on the second insulating layer 160. For example, each of the first and second circuit boards 100 and 150 may be implemented as an active metal brazed (AMB) substrate or a direct bonded copper (DBC) substrate, each of the first and second insulating layers 110 and 160 may be implemented as a ceramic layer, and each of the first and second metal layers 120 and 170 may be implemented as a copper layer, but is not limited thereto.

A portion of each of the first and second insulating layers 110 and 160 may overlap each of the first and second metal layers 120 and 170 in the vertical direction (e.g., a Z-direction), and the other portion of each of the first and second insulating layers 110 and 160 may not overlap each of the first and second metal layers 120 and 170 in the vertical direction (e.g., the Z-direction). For example, before patterning, each of the first and second metal layers may be formed to overlap the (e.g., entire) region of each of the first and second insulating layers 110 and 160, and a portion of each of the first and second metal layers before patterning may be removed by a patterning process (e.g., a photolithography process), and after patterning, each of the first and second metal layers 120 and 170 may include a plurality of patterns 122, 123, 124, 125, and 128 separated from each other, and the plurality of patterns 122, 123, 124, 125, and 128 may provide a plurality of electrical connection paths for the first and second semiconductor chips 201 and 301 of the first and second switching units 200 and 300.

For example, the first circuit board 100 may further include a third metal layer 130, and the second circuit board 150 may further include a fourth metal layer 180. For example, the third and fourth metal layers 130 and 180 may dissipate heat generated by the first and second semiconductor chips 201 and 301 and the first and second metal layers 120 and 170 to the outside of the power module for a vehicle and may be electrically separated from the first and second metal layers 120 and 170 by the first and second insulating layers 110 and 160. Alternatively, the third and fourth metal layers 130 and 180 may provide ground for the first and second switching units 200 and 300 and may be electrically connected to some patterns of the first and second metal layers 120 and 170 through conductive vias of the first and second insulating layers 110 and 160. Although not illustrated, cooling channels for cooling the power module for a vehicle may be in contact with a lower surface of the third metal layer 130 and an upper surface of the fourth metal layer 180.

The first and second switching units 200 and 300 may be electrically connected to a plurality of DC electrodes 410 and 420 and arranged on the first and second circuit boards 100 and 150 (e.g., arranged between the first and second circuit boards 100 and 150). For example, the first and second semiconductor chips 201 and 301 of the first and second switching units 200 and 300 may be implemented as at least one of an integrated circuit, a chip, and a die. Switching of the first and second switching units 200 and 300 may refer to switching between an ON state and an OFF state of the semiconductor device.

The first and second switching units 200 and 300 may receive a control signal from the outside of the power module through the signal lead 500 and may switch the ON/OFF state of the semiconductor device according to the control signal. According to the switching of the first and second switching units 200 and 300, the first and second switching units 200 and 300 may invert a DC current input through the lead frame 400 into an AC current.

For example, the first and second switching units 200 and 300 may be mounted on the upper surface of the first circuit board 100 via first and second connecting portions 215 and 315, respectively. For example, the first and second connecting portions 215 and 315 may be implemented as a structure also providing an electrical connection path, such as a bump or a solder ball, or may be implemented as an adhesive layer providing adhesiveness without an electrical connection path.

The lead frame 400 may include a plurality of DC electrodes 410 and 420 arranged on one side (e.g., in a −Y-direction) of the first and second circuit boards 100 and 150 and may further include an AC electrode 430. The plurality of DC electrodes 410 and 420 may include an N-type electrode and a P-type electrode. The plurality of DC electrodes 410 and 420 may be electrically connected to the battery (e.g., BAT of FIG. 1A), so that they may receive DC current from the battery (e.g., BAT of FIG. 1A) and transmit the DC current to the first and second semiconductor chips 201 and 301 through at least two of the plurality of patterns 122, 123, 124, 125, and 128 of the first metal layer 120. The AC electrode 430 may be electrically connected to the motor (e.g., 2 of FIG. 1A), and thus, the AC electrode 430 may receive AC current output from the first and second semiconductor chips 201 and 301 through the first metal layer 120 and output the same to the motor (e.g., 2 of FIG. 1A).

The embedded capacitors C-com, C-com1, C-com2, C-com3, and C-com4 may be electrically connected between the plurality of DC electrodes 410 and 420 and may be arranged (e.g., arranged between the first circuit board 100 and the second circuit board 150) to overlap at least one of the first insulating layer 110 and the first metal layer 120 in a direction (e.g., the Z-direction) in which the first insulating layer 110 and the first metal layer 120 face each other.

Since the first and second switching units 200 and 300 may be arranged on the first and second circuit boards 100 and 150, the embedded capacitors C-com, C-com1, C-com2, C-com3, and C-com4 arranged to overlap the first and second circuit boards 100 and 150 may be connected close to the first and second semiconductor chips 201 and 301 of the first and second switching units 200 and 300. Accordingly, the parasitic inductance (e.g., L-para in FIG. 1A) may be (e.g., efficiently) offset, and the voltage/current fluctuation/surge/ringing caused by the switching of the first and second semiconductor chips 201 and 301 may be (e.g., efficiently) reduced.

For example, a portion of the lead frame 400 may be disposed to overlap at least one of the first insulating layer 110 and the first metal layer 120 in a direction (e.g., the Z-direction) in which the first insulating layer 110 and the first metal layer 120 face each other, and the embedded capacitors C-com, C-com1, C-com2, C-com3, and C-com4 may be arranged to not overlap the lead frame 400 in a direction (e.g., the Z-direction) in which the first insulating layer 110 and the first metal layer 120 face each other. That is, compared to the lead frame 400, the embedded capacitors C-com, C-com1, C-com2, C-com3, and C-com4 may be arranged closer to the first and second semiconductor chips 201 and 301. Therefore, the embedded capacitors C-com, C-com1, C-com2, C-com3, and C-com4 may also offset the parasitic inductance of the lead frame 400.

For example, the AC electrode 430 of the lead frame 400 may further include a plurality of AC electrodes 430 electrically connected to the first switching unit 200 and/or the second switching unit 300, and the plurality of DC electrodes 410 and 420 may be arranged (e.g., adjacently) to not have a plurality of AC electrodes 430 therebetween. Accordingly, an electrical distance between the plurality of DC electrodes 410 and 420 and the first switching unit 200 may be shortened, and the transmission energy efficiency may be improved. Compared to the transmission energy efficiency of the AC current, the transmission energy efficiency of the DC current may have a greater impact on the overall energy efficiency of the power module for a vehicle.

As the electrical distance between the plurality of DC electrodes 410 and 420 and the first switching unit 200 becomes shorter, the parasitic inductance corresponding to the electrical distance may also become smaller, and the (e.g., required) capacitance of the embedded capacitor C-com, C-com1, C-com2, C-com3, and C-com4 to offset the parasitic inductance may also become smaller.

For example, the number of the plurality of DC electrodes 410 and 420 may be three, and the number of the plurality of AC electrodes 430 may be three, but is not limited thereto. For example, among the plurality of DC electrodes 410 and 420, two DC electrodes 420 on both sides may be N-type electrodes (or P-type electrodes), and among the plurality of DC electrodes 410 and 420, one DC electrode 410 in the middle may be a P-type electrode (or N-type electrode). This structure may be provided as an N-P-N busbar structure (or a P-N-P busbar structure).

Referring to FIGS. 2 and 3A, the power module for a vehicle according to an embodiment of the present disclosure may further include a fused portion 75 connected between the embedded capacitors C-com1 and C-com2 and the first metal layer 120 and including a conductive material having a lower melting point than that of the first metal layer 120. For example, the fused portion 75 may be implemented with a solder material or a sinter material and may be formed through a reflow process or a thermal compression bonding (TCB) process for a structure in which the embedded capacitors C-com1 and C-com2 are disposed on the first metal layer 120.

Since the embedded capacitors C-com1 and C-com2 (e.g., previously manufactured separately from the power module for a vehicle) may be connected to the power module for a vehicle by the fused portion 75, the embedded capacitors C-com1 and C-com2 may be implemented as capacitor components designed to (e.g., efficiently) form capacitance. For example, the capacitor components may be implemented as one of a multilayer ceramic capacitor (MLCC), a solid electrolytic (or tantalum) capacitor, a film capacitor, and a silicon wafer-based capacitor, but are not limited thereto.

For example, the embedded capacitors C-com1 and C-com2 may include a capacitor body 60 and a plurality of capacitor electrodes 70 and 80 arranged in the capacitor body 60. The capacitor body 60 may have a structure (e.g., efficiently) forming capacitance (e.g., a structure in which a metal-dielectric-metal structure is efficiently compressed). The plurality of capacitor electrodes 70 and 80 may provide an electrical path for transferring the capacitance of the capacitor body 60 to the outside of the embedded capacitor C-com1 and C-com2 and may be electrically connected to each of a plurality of separated patterns (e.g., two of 122, 123, 124, 125, and 128) of the first metal layer 120.

For example, the embedded capacitor C-com1 may be arranged in a bridge structure crossing between the plurality of patterns (two of 122, 123, 124, 125, and 128). Accordingly, a space between the plurality of patterns (two of 122, 123, 124, 125, and 128) may be (e.g., efficiently) utilized (e.g., utilized to secure the space (e.g., required) for capacitance formation), and the overall design freedom of the electrical connection paths provided by the first metal layer 120 may be further increased.

For example, the embedded capacitor C-com2 may further include a capacitor bonding wire 90 connected to one of the plurality of capacitor electrodes 70 and 80. One of the plurality of capacitor electrodes 70 and 80 may be electrically connected to one of the plurality of patterns (e.g., two of 122, 123, 124, 125, and 128) of the first metal layer 120 via the capacitor bonding wire 90, and the other of the plurality of capacitor electrodes 70 and 80 may be electrically connected to another of the plurality of patterns (e.g., two of 122, 123, 124, 125, and 128) of the first metal layer 120. Accordingly, the degree of freedom in shape and the degree of freedom in arrangement of the embedded capacitor C-com2 may increase. For example, the capacitor bonding wire 90 may include a material having high conductivity, ductility, and malleability, such as gold (Au), but is not limited thereto.

Referring to FIG. 2 and FIGS. 3B and 3C, one of the plurality of capacitor electrodes 70 and 80 of the embedded capacitor C-com3 and C-com4 may be electrically connected to the first metal layer 120, and the other of the plurality of capacitor electrodes 70 and 80 may be electrically connected to the second metal layer 170. Accordingly, the space between the first and second circuit boards 100 and 150 may be (e.g., efficiently) utilized, and the overall design freedom of the electrical connection paths provided by the first and second metal layers 120 and 170 may further increased.

Referring to FIGS. 2 and 3B, the power module for a vehicle according to an embodiment of the present disclosure may further include a capacitor spacer 630 disposed between the first and second circuit boards 100 and 150 to overlap the embedded capacitor C-com3 in a direction (e.g., the Z-direction) in which the first and second circuit boards 100 and 150 face each other. One of the plurality of capacitor electrodes 70 and 80 of the embedded capacitor C-com3 may be electrically connected to the first metal layer 120, and the other of the plurality of capacitor electrodes 70 and 80 may be electrically connected to the second metal layer 170 through the capacitor spacer 630.

For example, the capacitor spacer 630 may be implemented as a block formed of a conductive material or may be implemented as a structure in which a conductive pillar and an insulating block surrounding the conductive pillar are combined, but is not limited thereto. For example, the capacitor spacer 630 may be connected and bonded to the embedded capacitor C-com3 and the second metal layer 170 via the spacer connection portion 635.

Depending on the embodiment (e.g., design), a portion of the lead frame 400 may be connected to the first circuit board 100, the remainder of the lead frames 400 may be connected to the second circuit board 150, and the embedded capacitors C-com3 and C-com4 may be electrically connected between one of the lead frames 400 (e.g., connected to the first circuit board) and the other (e.g., connected to the second circuit board).

Depending on the embodiment (e.g., design), the capacitor spacer 630 may not provide an electrical connection path to the embedded capacitor C-com3. The capacitor spacer 630 may have a thickness corresponding to a difference between a gap between the first and second circuit boards 100 and 150 and a thickness of the embedded capacitor C-com3, so that the arrangement of the embedded capacitor C-com3 may be stabilized by supporting the embedded capacitor C-com3 downwardly.

Referring to FIGS. 2, 3B, and 3C, the power module for a vehicle according to an embodiment of the present disclosure may include a switching unit spacer 610 and/or a via spacer 620. The switching unit spacer 610 and the via spacer 620 may each provide an electrical connection path for the second circuit board 150, so that the capacitor electrode 80 of the embedded capacitor C-com3 and C-com4 may be electrically connected to the first and second semiconductor chips 201 and 301 or the plurality of DC electrodes 410 and 420.

The switching unit spacer 610 may be disposed between the first semiconductor chip 201 of the first switching unit 200 and the second circuit board 150 to electrically connect the first switching unit 200 and the second metal layer 170. The via spacer 620 may be disposed between the first circuit board 100 and the second circuit board 150 to electrically connect the first metal layer 120 and the second metal layer 170.

Spacer connection portions 615 and 625 may connect the switching unit spacer 610 and/or the via spacer 620 to the second metal layer 170, may connect the switching unit spacer 610 to the first semiconductor chip 201 of the first switching unit 200, and may connect the via spacer 620 to the first metal layer 120. For example, the spacer connection portions 615 and 625 may be implemented as a block formed of a conductive material or may be implemented as a structure in which a conductive pillar and an insulating block surrounding the conductive pillar are combined, but is not limited thereto.

The switching unit spacer 610 may stabilize the arrangement of the first semiconductor chip 201 by supporting the first semiconductor chip 201 of the first switching unit 200 downwardly and may also provide a path for dissipating heat generated by the first semiconductor chip 201 upwardly.

Referring to FIGS. 2 to 3D, the power module for a vehicle according to an embodiment of the present disclosure may further include at least one of an encapsulant 650, a current sensor (e.g., 800 of FIG. 2), a bonding wire 900, and a signal lead 500.

The encapsulant 650 may be disposed on the first circuit board 100, may be disposed between the first and second circuit boards 100 and 150, and may encapsulate the first, second and third switching units 200, 300, and 700 and the embedded capacitors C-com, C-com1, C-com2, C-com3, and C-com4. The encapsulant 650 may protect the first, second and third switching units 200, 300, and 700 from the outside of the power module for a vehicle, while also protecting the embedded capacitors C-com, C-com1, C-com2, C-com3, and C-com4. For example, the encapsulant 650 may include a molding material, such as epoxy molding compound (EMC), or a silicone gel, but is not limited thereto.

The current sensor (e.g., 800 of FIG. 2) may sense current flowing through the first metal layer 120 and may be disposed between the first and second circuit boards 100 and 150. For example, the current sensor (e.g., 800 of FIG. 2) may be implemented to sense current and/or voltage of a resistor shunt-connected to the first metal layer 120 or may be implemented as a hall sensor, but is not limited thereto.

One end of the bonding wire 900 may be connected to the first, second, and third switching units 200, 300, and 700 and the current sensor (e.g., 800 of FIG. 2), and the other end of the bonding wire 900 may be connected to the first metal layer 120 or the signal lead 500. For example, the bonding wire 900 may include a material having high conductivity, ductility, and electrical conductivity, such as gold (Au), but is not limited thereto.

The signal lead 500 may be electrically connected to the first, second, and third switching units 200, 300, and 700 and may be disposed on the other side (e.g., a +Y-direction) of the first and second circuit boards 100 and 150. The signal lead 500 may be disposed to be offset from the center of the first and second circuit boards 100 and 150 in the +Y-direction. The signal lead 500 may receive a control signal from the outside (e.g., a controller) of the power module for a vehicle and transmit the control signal to the first, second, and third switching units 200, 300, and 700. In addition, the signal lead 500 may transmit a current value sensed by the current sensor (e.g., 800 of FIG. 2) to the outside (e.g., the controller) of the power module for a vehicle.

Meanwhile, referring to FIG. 3D, the power module for a vehicle according to an embodiment of the present disclosure may have a structure in which the second circuit board (e.g., 150 of FIG. 3A), the switching unit spacer (e.g., 610 of FIG. 3A), and the via spacer (e.g., 620 of FIG. 3A) are omitted.

The power module for a vehicle including an embedded capacitor and the motor driving apparatus including the same according to an embodiment of the present disclosure may (e.g., efficiently) reduce the influence (e.g., fluctuation/surge/ringing of voltage/current due to switching for power conversion) of parasitic inductance of the power module for a vehicle, and may increase the power conversion efficiency of the power module for a vehicle (e.g., switching unit) or reduce the (e.g., required) specifications (e.g., withstand voltage characteristics).

While embodiments have been shown and described above, it may be apparent to those skilled in the art that modifications and variations may be made without departing from the scope of the present disclosure as provided by the appended claims.

What is claimed is:

1. A power module for a vehicle, the power module comprising:
a first circuit board including a first insulating layer and a first metal layer disposed on the first insulating layer;
a lead frame including a plurality of direct current (DC) electrodes disposed on the first circuit board;
a first switching unit electrically connected to the plurality of DC electrodes and disposed on the first circuit board; and
an embedded capacitor electrically connected between the plurality of DC electrodes,
wherein the embedded capacitor is disposed to overlap at least one of the first insulating layer and the first metal layer in a direction in which the first insulating layer and the first metal layer face each other.

2. The power module of claim 1, further comprising a fused portion connected between the embedded capacitor and the first metal layer, the fused portion including a conductive material having a lower melting point than a melting point of the first metal layer.

3. The power module of claim 1, wherein
the embedded capacitor includes a capacitor body, a plurality of capacitor electrodes disposed in the capacitor body, and a capacitor bonding wire configured to connect tat least one capacitor electrode of the plurality of capacitor electrodes to the first metal layer.

4. The power module of claim 1, further comprising an encapsulant disposed on the first circuit board and encapsulating the first switching unit and the embedded capacitor.

5. The power module of claim 1, further comprising:
a second circuit board including a second insulating layer and a second metal layer disposed on the second insulating layer,
wherein the embedded capacitor is disposed between the first circuit board and the second circuit board.

6. The power module of claim 5, wherein
the embedded capacitor includes a capacitor body and a plurality of capacitor electrodes disposed in the capacitor body, and
at least one capacitor electrode of the plurality of capacitor electrodes is electrically connected to the first metal layer and at least one capacitor electrode of the plurality of capacitor electrodes is electrically connected to the second metal layer.

7. The power module of claim 6, further comprising a via spacer disposed between the first circuit board and the second circuit board to electrically connect the first metal layer to the second metal layer.

8. The power module of claim 6, further comprising a switching unit spacer disposed between the first switching unit and the second circuit board to electrically connect the first switching unit to the second metal layer.

9. The power module of claim 6, further comprising:
a capacitor spacer disposed between the first circuit board and the second circuit board to overlap the embedded capacitor in a direction in which the first and second circuit boards face each other,
wherein at least one capacitor electrode of the plurality of capacitor electrodes is electrically connected to the second metal layer through the capacitor spacer.

10. The power module of claim 5, further comprising a capacitor spacer disposed between the first circuit board and the second circuit board to overlap the embedded capacitor in a direction in which the first and second circuit boards face each other.

11. The power module of claim 1, wherein
the embedded capacitor includes a capacitor body and a plurality of capacitor electrodes disposed in the capacitor body,
the plurality of capacitor electrodes are electrically connected to a plurality of separated patterns of the first metal layer, and
the embedded capacitor is disposed in a bridge structure crossing between the plurality of separated patterns.

12. The power module of claim 1, wherein
a portion of the lead frame is disposed to overlap at least one of the first insulating layer and the first metal layer in a direction in which the first insulating layer and the first metal layer face each other, and
the embedded capacitor is disposed to not overlap the lead frame in the direction in which the first insulating layer and the first metal layer face each other.

13. The power module of claim 1, wherein
the lead frame further includes a plurality of alternating current (AC) electrodes electrically connected to the first switching unit.

14. The power module of claim 13, wherein the plurality of DC electrodes are adjacent to not to have the plurality of AC electrodes therebetween.

15. The power module of claim 14, further comprising a signal lead electrically connected to the first switching unit and disposed on the first circuit board.

16. The power module of claim 14, wherein the plurality of DC electrodes are electrically connected to a DC link capacitor and a battery outside the power module for a vehicle.

17. The power module of claim 13, wherein the plurality of AC electrodes are electrically connected to a motor outside the power module for a vehicle.

18. The power module of claim 1, further comprising:
a second switching unit disposed on the first circuit board; and
a third switching unit disposed on the first circuit board,
wherein the first switching unit includes a plurality of first semiconductor chips, the second switching unit includes a plurality of second semiconductor chips, and the third switching unit includes a third semiconductor chip.

19. The power module of claim 18, wherein
the first switching unit is disposed in a central portion of the first circuit board,
the second switching unit is disposed on an outside of the first switching unit on the first circuit board, and
the third switching unit is disposed on the outside of the first switching unit on the first circuit board.

20. A motor driving apparatus comprising:
a power module comprising:
a first circuit board including a first insulating layer and a first metal layer disposed on the first insulating layer;
a lead frame including a plurality of direct current (DC) electrodes disposed on the first circuit board;
an embedded capacitor electrically connected between the plurality of DC electrodes, wherein the embedded capacitor is disposed to overlap at least one of the first insulating layer and the first metal layer in a direction in which the first insulating layer and the first metal layer face each other;
a first switching unit electrically connected to the plurality of DC electrodes and disposed on the first circuit board;
a second switching unit disposed on the first circuit board; and
a third switching unit disposed on the first circuit board,
wherein the first switching unit includes a plurality of first semiconductor chips, the second switching unit includes a plurality of second semiconductor chips, and the third switching unit includes a third semiconductor chip, wherein the first switching unit includes a 1-1 switching element and a 1-2 switching element and corresponds to a leg of a first inverter,
the second switching unit includes a 2-1 switching element and a 2-2 switching element and corresponds to a leg of a second inverter, and
at least one end of the third switching unit is connected between a first node between the 1-1 switching element and the 1-2 switching element and a second node between the 2-1 switching element and the 2-2 switching element and constitutes part of a changeover switch.
